(19) United States
(12) Patent Application Publication
(10) Pub. No.: US 2024/0210335 A1
(43) Pub. Date: Jun. 27, 2024

(54) APPARATUS FOR ANALYSING AND/OR PROCESSING A SAMPLE WITH A PARTICLE BEAM AND METHOD

(71) Applicant: Carl Zeiss SMT GmbH, Oberkochen (DE)

(72) Inventor: Daniel Rhinow, Frankfurt (DE)

(21) Appl. No.: 18/419,940

(22) Filed: Jan. 23, 2024

Related U.S. Application Data
(63) Continuation of application No. PCT/EP2022/072537, filed on Aug. 11, 2022.

(30) Foreign Application Priority Data
Aug. 11, 2021 (DE) 102021120913.7

(51) Int. Cl. G01N 23/2251; G01N 29/02; G01N 29/24; G03F 7/20; G03F 9/00

(52) U.S. Cl. CPC G01N 23/2251; G01N 29/02; G01N 29/2418; G01N 2291/021; G03F 7/2049; G03F 9/70

(57) ABSTRACT

What is proposed is an apparatus for analysing and/or processing a sample with a particle beam, comprising:

a providing unit for providing the particle beam; and

a test structure attached to the providing unit;

wherein the apparatus is configured for implementing an etching process and/or a deposition process on the test structure using the particle beam.

### CROSS-REFERENCE TO RELATED APPLICATIONS

This application is a continuation of and claims priority under 35 U.S.C. § 120 from PCT Application No. PCT/EP2022/072537, filed on Aug. 11, 2022, which claims priority from German Application No. 10 2021 120 913.7, filed on Aug. 11, 2021. The entire contents of each of these priority applications are incorporated herein by reference.

### TECHNICAL FIELD

The present invention relates to an apparatus for analysing and/or processing a sample with a particle beam and to a corresponding method.

### BACKGROUND

Microlithography is used for producing microstructured components, for example integrated circuits. The microlithography process is performed using a lithography apparatus, which has an illumination system and a projection system. The image of a mask (reticle) illuminated by means of the illumination system is in this case projected by means of the projection system onto a substrate, for example a silicon wafer, which is coated with a light-sensitive layer (photoresist) and arranged in the image plane of the projection system, in order to transfer the mask structure to the light-sensitive coating of the substrate.

In this case, the mask or else lithography mask is used for a great number of exposures, and so it is of huge importance for said mask to be free of defects. Therefore, a correspondingly great effort is made to examine lithography masks for defects and to repair identified defects. Defects in lithography masks can have an order of magnitude in the range of a few nanometres. Repairing such defects necessitates apparatuses which offer a very high spatial resolution for the repair processes.

Appropriate apparatuses for this purpose activate local etching or deposition processes on the basis of particle beam-induced processes.

EP 1 587 128 B1 discloses one such apparatus that uses a beam of charged particles, in particular an electron beam of an electron microscope, for initiating the chemical processes. Use of charged particles can give rise to charging of the sample provided that the latter is not or only poorly conductive. This can lead to uncontrolled beam deflection, which limits the achievable process resolution. It is therefore proposed to arrange a shielding element very close to the processing position, thereby minimizing the charging of the sample and improving the process resolution and control.

DE 102 08 043 A1 discloses a material processing system usable in methods for material processing by means of material deposition from gases, for instance chemical vapour deposition (CVD) or material removal with reaction gases being fed in. In this case, in particular, the gas reaction that results in a material deposition or in a material removal is initiated by an energy beam directed at a region of the workpiece to be processed.

DE 10 2019 200 696 B4 discloses a device for determining a position of an element on a photomask. Markers 550, 850 and 950 are used.

In order to be able to implement processes of this kind accurately, high control over a wide variety of different operating parameters of the apparatus is required. To date, methods of beam analysis or of analysis of material contrasts, or the analysis of particle beam-induced processes, such as etching processes or deposition processes, for example in the startup of a process, have required the loading of various samples into the apparatus. Since it is necessary here to interrupt the operation of the apparatus every time and, for example, the process atmosphere is broken, differences in operation may arise in the subsequent process in spite of nominally the same operating parameters of the apparatus. This relates, for example, to the collimation of the particle beam, operating parameters of detectors, valve settings for process gases and the like. In addition, it has been possible to date to ascertain an actual composition of the process atmosphere only in a complex manner and with a time delay, which makes it difficult to monitor the process.

### SUMMARY

It is therefore desirable to determine and/or to control significant operating and/or process parameters for the performance of an analysis and/or a processing operation in situ without having to interrupt the operation of the apparatus for this purpose, especially with retention of the process atmosphere.

Against this background, it is an aspect of the present invention to provide an improved apparatus for analysing and/or processing a sample with a particle beam, and a corresponding method.

In accordance with a first aspect, an apparatus for analysing and/or processing a sample with a particle beam is proposed. The apparatus comprises:
a providing unit for providing the particle beam,
a shielding element for electrical and/or magnetic shielding,
wherein the shielding element has a through opening for the particle beam to pass through to the sample,
wherein the shielding element and/or a holding element for holding the shielding element has at least one test structure,
an aligning unit for aligning the particle beam, the shielding element and/or the holding element, such that the particle beam can be incident on the test structure, and
a determining unit for determining at least one current operating parameter and/or process parameter of the apparatus depending on an interaction of the particle beam with the test structure when the particle beam is incident on the test structure.

This apparatus has the advantage that the at least one current operating parameter and/or process parameter can be determined in situ. This means that the current operating parameter and/or process parameter for a planned analysis and/or processing operation on the sample already introduced into the apparatus can first be ascertained using the test structure, and then the analysis and/or processing operation can be implemented on the basis of the current operating and/or process parameter determined. This differs from existing apparatuses particularly in that the sample has already been introduced and, therefore, the process atmosphere is maintained continuously during the determining and the subsequent analysis or processing. A possibility of in situ process control is thus created. In particular, it is possible in this way first to optimally set or adjust the respective operating and/or process parameters before commencing with the analysis and/or processing.

The sample is for example a lithography mask having a feature size in the range of 10 nm-10 μm. This may be, for example, a transmissive lithography mask for DUV lithography (DUV: “deep ultraviolet”, operating light wavelengths in the range of 30-250 nm) or a reflective lithography mask for EUV lithography (EUV: “extreme ultraviolet”, operating light wavelengths in the range of 1-30 nm). The processing processes that are carried out in this case comprise for example etching processes, in which a material is locally removed from the surface of the sample, deposition processes, in which a material is locally applied to the surface of the sample, and/or similar locally activated processes, such as forming a passivation layer or compacting a layer.

The particle beam is especially charged particles, such as ions, electrons or positrons, for example. Accordingly, the providing unit has a beam generating unit comprising an ion source or an electron source, for example. The particle beam composed of charged particles can be influenced, that is to say for example accelerated, directed, shaped and/or focused, by use of electric and magnetic fields. For this purpose, the providing unit can have a number of elements configured for generating a corresponding electric and/or magnetic field. Said elements are arranged in particular between the beam generating unit and the shielding element. The particle beam is preferably focused onto the test structure to determine the current operating and/or process parameter. This is understood to mean for example that the particle beam has a predefined diameter, in particular a smallest diameter, when it hits the test structure. The providing unit preferably comprises a dedicated housing with the aforementioned elements arranged therein, the housing preferably being embodied as a vacuum housing, which is kept at a residual gas pressure of 10⁻⁶-10⁻⁸ mbar, for example.

The shielding element may be held by a holding element. The shielding element is disposed, for example by use of the holding element, at or on an opening in the provision unit through which the particle beam is guided onto the sample at a processing position, and forms especially the closest component of the providing unit to a sample stage for the apparatus in beam direction. The connection between the holding element and the shielding element can be effected by welding, clamping and/or by adhesive bonding, for example. The holding element and the shielding element may be in a one-part or one-piece design. “One-part” means that the holding element and the shielding element are combined to form one unit. This can be effected in a force-locking, form-fitting and/or cohesive manner. A force-locking connection presupposes a normal force on the surfaces to be connected to one another. Force-fit connections can be obtained by frictional engagement. The mutual displacement of the faces is prevented as long as the counterforce brought about by the static friction is not exceeded. A force-locking connection can also be present as a magnetic force-locking engagement. An interlocking connection is obtained by at least two connection partners engaging one inside the other or one behind the other. In cohesive connections, the connection partners are held together by atomic or molecular forces. Cohesive connections are non-releasable connections that can be separated only by destruction of the connection means. Cohesive enables connection by, e.g., adhesive bonding, soldering or welding. What is meant by “one-piece” in the present context is that the holding element and the shielding element have been produced from one and the same material in a primary forming process, for instance casting or extruding.

The holding element may take the form of a securing means that secures the shielding element on the providing unit or on a vacuum housing thereof.

The holding element has been produced, for example, partly or wholly from nickel-silver. The shielding element has been produced, for example, partly or wholly from nickel.

In embodiments, the holding element and the shielding element take the form of one component, in particular in monolithic form. This is possible by use of special production methods, in particular LIGA fabrication methods (LIGA: an abbreviation from the German Lithographie, Galvanik und Abformung [lithography, electroplating and moulding]).

The apparatus is a scanning electron microscope, for example. In order to achieve a high resolution, the electron beam should be controlled very accurately, in particular with regard to the electron energy, a beam diameter upon impinging on the sample (referred to hereinafter as focus) and a temporal stability of the impingement point. Particularly in the case of samples having sections composed of an electrically non-conductive or only slightly conductive material, the incidence of the charged particles results in an accumulation of charges on the sample that form an electric field. The particles of the particle beam, but also for example secondary electrons and backscattered electrons that are detected in order to generate an image, are influenced by the electric field, which can result in a reduction of the resolution, for example.

The electrical shielding element may be a shielding element for shielding an electric field generated by charges accumulated on the sample. For example, the shielding element fulfils the task of shielding the electric field of said charges, that is to say of spatially delimiting said electric field, in particular to a smallest possible gap between the shielding element and the sample. For this purpose, the shielding element comprises an electrically conductive material. By way of example, the shielding element is earthed, such that charges that impinge on the shielding element are dissipated. In other embodiments, the shielding element shields a magnetic field. In addition, it may be the case that the electrical and/or magnetic field is not produced (or not produced exclusively) by the sample (especially by charges accumulated thereon). The electrical and/or magnetic field may also originate within the apparatus, especially within the providing unit (for example within the electron beam column), or be located elsewhere.

The shielding element itself is preferably in two-dimensional form. The surface may form a three-dimensional form, the surface of which has a convex section in the direction of the sample stage. The convex section preferably forms the closest section to the sample stage, that is to say that the distance between the sample stage or the sample and the shielding element is at its smallest in the region of the convex section. In the convex section the shielding element has a through opening, through which the particle beam passes and is incident on the sample. In a spatial region above the shielding element from where the particle beam comes, an electric field of charges situated on the sample is effectively shielded by the shielding element. It should be noted that the shielding element can have further through openings, wherein one or more through openings can also be arranged outside the convex section of the shielding element. It should be noted that the term “convex” should be understood here from the point of view of the beam source. From the point of view of the sample or sample stage, the convex section may also be considered to be a concave section. The shielding element, apart from the convex section, may also comprise a concave section. The convex section may also be referred to as a swelling or bulge in the shielding element in the direction toward the sample stage.

By way of example, the convex section of the shielding element is at a distance from the sample of at most 100 μm, preferably at most 50 μm, preferably at most 25 μm, more preferably at most 10 μm, during an analysis or processing of the sample with the particle beam. The smaller the distance, the less an electrical interference field can influence the particle beam.

Consequently, the particle beam, during the analysis and/or processing of the sample, can be controlled very accurately and is subject to random and/or uncontrollable interference influences to a lesser extent. A very high resolution is thus possible, both during image acquisition, as in a scanning electron microscope, and during processing methods that are carried out with the particle beam, such as particle beam-induced etching or deposition processes, ion implantation, and/or further structure-altering processes.

The providing unit is an electron column, for example, which can provide an electron beam having an energy in a range of 10 eV-10 keV and a current in a range of 1 uA-1 pA. It may alternatively be an ion source that provides an ion beam. During the analysis and/or processing of the sample, the particle beam is preferably focused onto the surface of the sample, with achievement, for example, of an irradiation region with a diameter in the range of 1 nm-100 nm.

The holding element for holding the shielding element is preferably electrically conductive and has the same electrical potential as the shielding element. The holding element is thus also set up to shield the electrical field. The holding element may take the form of a mechanical securing of the shield element. In preferred embodiments, the holding element together with the shielding element is designed to be movable relative to the sample and/or relative to the providing unit (especially by use of the aligning unit), for example by securing the holding element by use of a suitable bearing on a housing of the providing unit, in which case an actuator may be provided to establish a position of the holding element. Alternatively or additionally, the shielding element may be held in a movable manner by the holding element. Therefore, some examples at the outset are elucidated in that the aligning unit is set up to align the particle beam, the shielding element and/or the holding element such that the particle beam can be incident on the test structure.

The holding element and/or the shielding element has the test structure by means of which the operating parameter and/or the process parameter is determinable. The test structure is formed depending in particular on the operating parameter or process parameter to be determined. This means that the test structure is suitably adapted and formed for a respective operating parameter or process parameter to be determined. In particular, the test structure may have differently formed regions for different operating parameters and/or process parameters to be determined. Alternatively or additionally, it is possible to provide multiple different test structures disposed both on the shielding element and on the holding element. For example, a test structure may comprise a structure having a particular spatial resolution for ascertaining a resolution of an electron microscope.

The test structure here is especially disposed on one side of the holding element and/or shielding element facing the providing unit.

The aligning unit may comprise both a mechanically active unit and an electrically and/or magnetically active unit. A mechanically active unit is set up, for example, to move the holding element and/or the shielding element such that the particle beam, rather than passing through the opening in the shielding element, hits and hence interacts with the test structure. An electrically and/or magnetically effective unit is set up, for example, to deflect the particle beam, for example in that operating parameters of a deflecting unit of the providing unit are adjusted appropriately such that the particle beam, rather than passing through the opening in the shielding element, hits the test structure.

An operating parameter in the present context is especially understood to mean a setting of the apparatus which is valid at a particular juncture, and a process parameter is especially understood to mean a parameter that can be determined by means of implementation of a process.

Operating parameters that can be determined with the apparatus proposed include settings of the providing unit, especially a current, an acceleration voltage and/or a respective voltage of beam guiding and beam forming elements in the case of an electron column, settings of detectors such as a secondary electron detector and/or a backscattered electron detector, a composition of a process atmosphere, especially a partial pressure of one or more process gases supplied, and the like.

Process parameters that can be determined with the apparatus proposed include a current etch rate of an etching process and/or a current deposition rate of a deposition process, a spatial resolution of an etching process and/or a deposition process and the like.

In embodiments, the apparatus comprises a vacuum housing for providing a vacuum therein, wherein at least the holding element and the shielding element are disposed within the vacuum housing.

In one embodiment of the apparatus, the test structure has a structure with a spatial resolution at spatial frequencies of 1/μm-1000/μm.

The structure may be provided, for example, by two different materials that are in an alternating arrangement for example. When the particle beam takes the form of an electron beam, suitable materials for this purpose are especially materials having a maximum difference in their atomic number.

The structure may also comprise a topographic structure comprising, for example, trenches arranged in lines and elevations with a very narrow transition region.

The structure may also comprise an arrangement of materials having discrete edges with respect to one another, which lead to steep changes in contrast in the secondary electron image, on the basis of which beam parameters can be determined.

The structure preferably has multiple regions each with different spatial resolution.

With this test structure, it is possible to undertake calibration of the providing unit and/or the particle beam, such that it attains, for example, a particular minimum resolution, which can ensure that features on the sample that have a minimum size corresponding to the minimum resolution are reliably determinable in an analysis and/or processing operation.

The test structure may especially be produced in situ, for example by means of a particle beam-induced deposition and/or etching process.

In a further embodiment of the apparatus, the test structure includes at least one particular first material and a particular second material other than the first material for providing a particular material contrast.

On the basis of the particular material contrast provided in such a way, it is especially possible to implement calibration of a secondary electron detector and/or a backscattered electron detector. This ensures that features on the sample are reliably determinable with an optimally set contrast in an analysis and/or processing operation.

The particular material contrast relates more particularly to a particular difference in the atomic number of the first and second materials. The particular first element here has a particular first atomic number, and the particular second element has a correspondingly selected particular second atomic number, which are different from one another.

In a further embodiment of the apparatus, it includes a detector for detecting backscattered electrons and/or secondary electrons, wherein the particular first material and the particular second material are selected such that the detector can be calibrated to detect backscattered electrons and/or secondary electrons by means of the particular material contrast.

The test structure preferably comprises the same materials as present on the sample. This encompasses both the materials of which the sample itself consists and materials that are known to possibly occur in the form of impurities on the sample. It is thus possible to provide the same material contrast which is likewise present in the analysis and/or processing of the sample, which improves detection of a sample structure and/or defect sites on the sample and/or process control of a process implemented on the sample.

In a further embodiment of the apparatus, the test structure has a predetermined area for implementation of an etching process and/or a deposition process.

The predetermined area especially consists of a particular material suitable for testing and/or adjustment of process parameters for an etching process and/or deposition process.

For example, in the case of transmissive photomasks, chromium, molybdenum-silicon and/or silicon nitride are used for the structuring of the absorbing layer, and in the case of reflective photomasks, tantalum and/or tantalum nitride. In order to repair any defect in such a photomask in a controlled manner, for example, excess material is removed, which can be effected in a particle beam-induced etching process. Therefore, a suitable material for the predetermined area is chromium and/or molybdenum-silicon and/or silicon nitride and/or tantalum and/or tantalum nitride. It should be noted that the predetermined area may consist of multiple sections each comprising different materials.

The test structure having the predetermined area may also be set up to determine a beam profile and/or a beam quality of the particle beam, for example in that the particle beam is radiated onto the test structure at multiple sites on the test structure, so as to result in a local change in the test structure depending on a local intensity of the particle beam. By measuring the size of or analysing the altered region, it is possible to determine information relating to the beam profile of the particle beam. In this way, it is possible to ascertain, for example, whether the particle beam has a preferred beam profile and/or a preferred focus. The altered region is preferably analysed by microscope imaging of the test structure or the altered region, especially by use of an electron micrograph. For example, it is possible to use a diameter and an appearance of a crater (in the case of an etching process) or of an elevation (in the case of a deposition process) to conclude the beam diameter and/or a beam form and/or an intensity distribution within the particle beam. For example, this can be effected at multiple positions in the test structure, by setting a different focus position of the particle beam at each of the different positions. It is thus possible to determine the beam profile for multiple section planes, which permits additional conclusions, especially with regard to possible causes in cases where the beam profile does not have the intended appearance.

In a further embodiment of the apparatus, the predetermined area for implementation of the etching process and/or the deposition process has an identical material composition to the sample.

In this embodiment, the operating parameters that lead to predetermined process parameters by means of which the sample is to be analysed and/or processed can advantageously be determined from the test structure in advance, i.e. before commencement of the analysis and/or processing of the sample. Since the analysis and/or processing of the sample can subsequently be conducted under exactly the same conditions, especially in the same process atmosphere, the analysis and/or processing can be conducted in a particularly exact and reliable manner. It is thus possible both to reduce a processing duration and to reduce the level of reject samples. In addition, it is possible to adjust the operating parameters over multiple processes and/or samples exactly in each case, such that the predetermined process parameters are attained. This means that, rather than assuming that the same operating parameters will always lead to the same process parameters, it is possible thereby already to determine the operating parameters in advance, such that the process parameters can be kept constant over multiple processes and/or samples.

In a further embodiment of the apparatus, the test structure is disposed on a side of the holding element and/or of the shielding element that faces the providing unit.

In a further embodiment of the apparatus, the aligning unit comprises a movement unit for in situ movement of the holding element and/or the shielding element and/or a particle beam deflection unit, wherein the particle beam deflection unit is set up to steer the particle beam either onto the through opening or onto the test structure.

In a second aspect, an apparatus for analysing and/or processing a sample with a particle beam is proposed. The apparatus comprises:
a providing unit for providing the particle beam;
a shielding element for electrical and/or magnetic shielding;
wherein the shielding element has a through opening for the particle beam to pass through to the sample,
an exciter unit for inducing a holding element for holding the shielding element, the shielding element and/or a vibrating element disposed on the holding element or the shielding element to mechanically vibrate,
a detecting unit for detecting a vibration property of the holding element, shielding element and/or vibrating element that has been induced to vibrate, and
a determining unit for determining at least one current operating parameter and/or process parameter of the apparatus depending on the vibration property detected.

This apparatus has the same advantages that have been elucidated for the apparatus in the first aspect. The embodiments and features that have been described for the apparatus in the first aspect and the elucidations and definitions are correspondingly applicable to the apparatus in the second aspect, and vice versa. In particular, the apparatus in one aspect may likewise have the additional features of the apparatus in the respective other aspect.

By use of this apparatus, it is especially possible to determine those operating parameters and/or process parameters that affect vibration of the holding element, the shielding element and/or the vibrating element. These are especially parameters that affect a vibrating mass and/or a reset force and/or a damping of the vibration of the respective vibrating element.

For easier understanding, the holding element, shielding element or vibrating element may be imagined as a spring-mass system. Such a system, in simplified terms, has three parameters that determine the vibration characteristics. These parameters are the spring constant (unit: N/m), the mass (unit: g) and the damping (unit, for example: N·s/m). On the basis of these three parameters, it is possible to predict the vibration characteristics depending on the excitation, or it is conversely possible to ascertain at least one of the parameters by detecting (measuring) the vibration characteristics after excitation.

The holding element, the shielding element and/or the vibrating element here, according to the design of these and the points to which they are fixed, may have different vibration modes that can be induced by use of the exciter unit. The inducible vibration modes here may especially include two-dimensional or three-dimensional modes. The holding element and/or the shielding element may each be specifically optimized for this use, meaning that these have a mechanical construction such that particular vibration modes are inducible. The vibrating element is especially an element envisaged especially for this application, for example a cantilever secured at one end or else a vibration bar secured at both ends.

The holding element, the shielding element and/or the vibrating element may especially have a test structure, as elucidated for the first aspect, especially a predetermined area suitable and intended for implementation of a particle beam-induced deposition and/or etching process.

The exciter unit comprises, for example, an electrostrictive element, for example a piezo actuator or the like. The exciter unit is especially set up to induce the particular element to mechanically vibrate with a particular frequency from a particular frequency band. It can also be said that the exciter unit provides a variable exciting frequency.

The detecting unit may likewise comprise an electrostrictive element. In particular, the exciter unit may first function as exciter and then as detecting unit.

Alternatively or additionally, the detecting unit may be set up to detect the vibration property in an optical manner.

The vibration property may include any characteristic parameter of a mechanical vibration of a body. Examples are an amplitude, a damping, a frequency, especially a resonance frequency and/or a multiple of a resonance frequency. The amplitude and the damping here are preferably detected as a function of the exciter frequency. The respective vibration property is especially time-dependent. In embodiments, it is also possible to detect a progression of the vibration property against time, and the progression of the vibration property against time can be used to ascertain a progression of an operating parameter and/or process parameter against time.

On the basis of the vibration property detected, it is possible using corresponding physical and/or mathematical models, for example, to ascertain mechanical parameters of the respective vibrating element, such as a modulus of elasticity, a mass, a mass distribution, a cross-sectional shape and the like.

The determining unit may be implemented in the form of hardware and/or software. In the case of a hardware implementation, the determining unit may take the form, for example, of a computer or microprocessor. In the case of a software implementation, the determining unit may take the form of a computer program product, of a function, of a routine, of an algorithm, of part of a program code or of an executable object.

In one embodiment of the apparatus, the exciter unit and/or the detecting unit is disposed on and held by the holding element.

In a further embodiment of the apparatus, the vibrating element comprises at least one cantilever.

The vibrating element or cantilever are especially disposed on the holding element and/or the shielding element in such a way that the particle beam can radiate onto a side of the vibrating element facing the providing unit. This means that the vibrating element is not concealed from the point of view of the particle beam. For example, the vibrating element is disposed in a further opening of the shielding element.

It may be the case that multiple cantilevers are arranged in parallel to one another, in which case the vibration property can be determined separately for each cantilever.

In a further embodiment of the apparatus, the detecting unit is set up to detect the vibration property by use of a laser.

This means that the detecting unit includes a laser, the laser beam from which is directed, for example, onto the holding element, the shielding element and/or the vibrating element, and includes a photodiode or the like that detects reflection of the laser beam, it being possible to determine a deflection of the vibrating element on the basis of a shift in the point of incidence of the reflected laser beam.

In a further embodiment of the apparatus, it comprises a process gas provision unit for providing a process gas in the sample, wherein the determining unit is set up to determine at least one partial pressure and/or at least one gas concentration of a species present in the process gas depending on the vibration property detected.

What is meant by providing of the process gas in the sample in the present context is more particularly that the process gas is guided to the sample and emitted in the immediate proximity of the sample. For example, the apparatus comprises a gas feed set up to guide a process gas through the passage opening of the shielding element to the sample. In this case, the process gas flows in the direction of the particle beam through the through opening. Thus, the process gas is especially also present in the region of the holding element, the shielding element and/or the vibrating element and surrounds or flows around it, with a process gas composition being essentially identical to that of the sample.

The partial pressure and/or gas concentration can be ascertained depending on the vibration property on the basis of physical and/or mathematical models that describe adsorption of gas molecules onto surfaces, and/or on the basis of reference measurements and/or calibration curves. An overview of this technology is given, for example, by the article “Recent advances in gas phase microcantilever-based sensing” by the authors Z. Long, L. Kou, M. Sepaniak and X. Hou, published in 2013 in volume 32/edition 2 of the journal “Reviews in Analytical Chemistry” by De Gruyter Verlag (DOI: https://doi.org/10.1515/revac-2012-0034).

In a third aspect, a method of analysing and/or processing a sample with a particle beam by means of an analysis and/or processing operation in an apparatus is proposed. The method comprises the steps of:
providing a test structure in a vacuum housing of the apparatus,
evacuating the vacuum housing to provide a process atmosphere for implementation of the analysis and/or processing operation,
radiating the particle beam onto the test structure,
detecting an interaction of the particle beam with the test structure, and
determining at least one current operating parameter and/or process parameter for the analysis and/or processing operation depending on the interaction detected.

This method is preferably implemented with the apparatus according to the first aspect. The advantages mentioned for the apparatus according to the first aspect are likewise applicable to the method proposed. The embodiments and features specified for the apparatus according to the first aspect are correspondingly applicable to the method proposed.

In embodiments of the method, it comprises implementing a test analysis and/or a test processing of the test structure in the process atmosphere to ascertain the current operating parameters and/or process parameters. This means that the analysis and/or processing operation with which the sample is to be analysed and/or processed is implemented by way of a test on the test structure or with the test structure.

Preferably, the evacuating of the vacuum housing is already preceded by introduction of the sample into the vacuum housing; for example, the sample is already put into the later processing position. It is then possible, after the operating parameter and/or process parameter has been determined, to implement the analysis and/or processing operation directly without having to break or disrupt the process atmosphere (the atmosphere in the vacuum housing).

In embodiments of the method, this further comprises:
adjusting at least one operating parameter of the apparatus depending on the current operating parameter and/or process parameter determined, and
implementing the analysis and/or processing operation in the process atmosphere using the adjusted operating parameter.

In this embodiment, the analysis and/or processing operation is optimized and therefore implementable with greater reliability and exactness. This increases the quality of the analysis and/or processing of the sample.

In a fourth aspect, a method of analysing and/or processing a sample with a particle beam by means of an analysis and/or processing operation in an apparatus is proposed. The apparatus has a shielding element for electrical and/or magnetic shielding, wherein the shielding element has a through opening for the particle beam to pass through to the sample. The method comprises the steps of:
evacuating a vacuum housing of the apparatus to provide a process atmosphere for implementation of the analysis and/or processing operation,
inducing a holding element for holding the shielding element, the shielding element and/or a vibrating element disposed on the holding element or the shielding element to mechanically vibrate,
detecting a vibration property of the holding element, shielding element and/or vibrating element that has been induced to vibrate, and
determining at least one current operating parameter and/or process parameter of the apparatus depending on the vibration property detected.

This method is preferably implemented with the apparatus according to the second aspect. The advantages mentioned for the apparatus according to the second aspect are likewise applicable to the method proposed. The embodiments and features specified for the apparatus according to the second aspect are correspondingly applicable to the method proposed.

In one embodiment of the method, the holding element, the shielding element and/or the vibrating element has a predetermined area of a particular material, and the method further comprises the steps of:
detecting the vibration property at at least two different junctures, and
determining a current etch rate of the particular material depending on a change in the vibration property.

Depending on the material that forms the particular material and the composition of the process atmosphere, especially which process gases are currently being supplied and/or have been supplied in a preceding process, the material may be subject to spontaneous etching by the residual process gas present in the process atmosphere. The expression “spontaneous etching” is understood here to mean that material removal takes place unintentionally and/or without having been triggered in a controlled manner by supply of energy or the like at the current juncture. The etching operation results in a decrease in a vibrating mass and/or thickness of the vibrating element, and there is therefore a change, for example, in the resonance frequency of the vibrating element. This can be used to ascertain an average removal of material over the observation period and hence also determine the current etch rate. The etch rate can be used, for example, to conclude a partial pressure of the etch gas in the process atmosphere and/or a residual gas concentration of the etch gas. The method is therefore especially suitable for determining contamination of the vacuum housing with unwanted gases, where the unwanted gas may especially be a process gas from a preceding process.

In embodiments of the method, the particle beam for implementing a particle beam-induced etching process is radiated onto the test structure (in particular its predetermined area), especially radiated in a focused manner. It is especially possible thereby to determine whether an activatable precursor gas of an etching gas is present in the process atmosphere, and the concentration thereof. Alternatively or additionally, a current etch rate can be determined for a planned etching process on the sample, in which case, for example, operating parameters of the apparatus can be adjusted in order to influence the etch rate in a controlled manner.

In a further embodiment of the method, it further comprises the steps of:
feeding a process gas to the holding element, the shielding element and/or the vibrating element,
radiating the particle beam onto a predetermined area of the holding element, the shielding element and/or the vibrating element for implementation of a particle beam-induced deposition process and/or etching process on the predetermined area,
detecting the vibration property at at least two different junctures between which the particle beam has been radiated, and
determining a deposition rate of the particle beam-induced deposition process or an etch rate of the particle beam-induced etching process depending on a change in the vibration property.

Alternatively and/or additionally to the deposition rate, it is possible to determine further properties of the deposit, such as a density. For this purpose, for example, the mass of the deposit is ascertained on the basis of the vibration property, and the volume of the deposit is ascertained on the basis of a microscope image, especially an electron micrograph, of the deposit.

Appropriate process gases suitable for depositing material or for growing elevated structures are, in particular, alkyl compounds of main group elements, metals or transition elements. Examples thereof are (cyclopentadienyl)trimethylplatinum CpPtMe₃ (Me=CH₄), (methylcyclopentadienyl)trimethylplatinum MeCpPtMe₃, tetramethyltin SnMe₄, trimethylgallium GaMe₃, ferrocene Cp₂Fe, bis-arylchromium Ar₂Cr, and/or carbonyl compounds of main group elements, metals or transition elements, such as, for example, chromium hexacarbonyl Cr(CO)₆, molybdenum hexacarbonyl Mo(CO)₆, tungsten hexacarbonyl W(CO)₆, dicobalt octacarbonyl Co₂(CO)₈, triruthenium dodecacarbonyl Ru₃(CO)₁₂, iron pentacarbonyl Fe(CO)₅, and/or alkoxide compounds of main group elements, metals or transition elements, such as, for example, tetraethyl orthosilicate Si(OC₂H₅)₄, tetraisopropoxytitanium Ti(OC₃H₇)₄, and/or halide compounds of main group elements, metals or transition elements, such as, for example, tungsten hexafluoride WF₆, tungsten hexachloride WCl₆, titanium tetrachloride TiCl₄, boron trifluoride BF₃, silicon tetrachloride SiCl₄, and/or complexes comprising main group elements, metals or transition elements, such as, for example, copper bis(hexafluoroacetylacetonate) Cu(C₅F₆HO₂)₂, dimethylgold trifluoroacetylacetonate Me₂Au(CsF₃H₄O₂), and/or organic compounds such as carbon monoxide CO, carbon dioxide CO₂, aliphatic and/or aromatic hydrocarbons, and the like.

Appropriate process gases suitable for etching material are for example: xenon difluoride XeF₂, xenon dichloride XeCl₂, xenon tetrachloride XeCl₄, water vapour H₂O, heavy water D₂O, oxygen O₂, ozone O₃, ammonia NH₃, nitrosyl chloride NOCI and/or one of the following halide compounds: XNO, XONO₂, X₂O, XO₂, X₂₀₂, X₂₀₄, X₂₀₆, where X is a halide. Further process gases for etching material are specified in the present applicant's US patent application having the Ser. No. 13/103,281.

Additional gases, which can for example be added in proportions to the process gas in order to better control the processing process, comprise for example oxidizing gases such as hydrogen peroxide H₂O₂, nitrous oxide N₂O, nitrogen oxide NO, nitrogen dioxide NO₂, nitric acid HNO₃ and other oxygen-containing gases, and/or halides such as chlorine Cl₂, hydrogen chloride HCl, hydrogen fluoride HF, iodine I₂, hydrogen iodide HI, bromine Br₂, hydrogen bromide HBr, phosphorus trichloride PCl₃, phosphorus pentachloride PCl₅, phosphorus trifluoride PF₃ and other halogen-containing gases, and/or reducing gases, such as hydrogen H₂, ammonia NH₃, methane CH₄ and other hydrogen-containing gases. These additional gases can be used, for example, for etching processes, as buffer gases, as passivating media and the like.

According to another aspect, there is provided an apparatus for analysing and/or processing a sample with a particle beam, comprising:
a providing unit for providing the particle beam; and
a test structure attached to the providing unit;
wherein the apparatus is configured for implementing an etching process and/or a deposition process on the test structure using the particle beam.

According to an embodiment, the apparatus further comprises a determining unit for determining at least one current operating parameter and/or process parameter of the apparatus depending on an interaction of the particle beam with the test structure on which the etching process and/or a deposition process has been implemented.

According to an embodiment, the test structure is arranged inside an inner volume defined by the providing unit.

According to an embodiment, the apparatus further comprises an electron microscope, wherein the test structure is arranged within a depth of field of the electron microscope.

According to an embodiment, the apparatus comprises the test structure on which the etching process and/or the deposition process has been implemented.

According to an embodiment, the apparatus comprises a process gas providing unit for providing a process gas to the test structure to implement the etching process and/or the deposition process thereon using the particle beam.

According to an embodiment, the providing unit has an opening for the particle beam to pass through to the sample, wherein the test structure is arranged inside or adjacent to the opening.

According to an embodiment, the apparatus further comprises a shielding element for electrical and/or magnetic shielding, wherein the shielding element has a through opening for the particle beam to pass through to the sample, wherein the shielding element and/or a holding element for holding the shielding element comprises the test structure.

According to an embodiment, the apparatus comprises an aligning unit for aligning the particle beam and the test structure relative to each other such that the particle beam is incident on the test structure.

According to an embodiment, the at least one determined operating parameter comprises a telecentricity of the providing unit.

According to an embodiment, the apparatus comprises:
an exciter unit for inducing the test structure to mechanically vibrate,
a detecting unit for detecting a vibration property of at least the test structure, and
a determining unit for determining at least one current operating parameter and/or process parameter of the apparatus depending on the vibration property detected.

According to an embodiment, the test structure is formed on a cantilever.

According to an embodiment, the detecting unit is set up to detect the vibration property by use of a laser.

According to an embodiment, the apparatus further comprises a process gas provision unit for providing a process gas to the sample, wherein the determining unit is set up to determine at least one partial pressure and/or at least one gas concentration of a species present in the process gas depending on the vibration property detected.

According to a further aspect, there is provided a system comprising the apparatus as described above and a sample.

According to an embodiment, the apparatus is configured for implementing an etching process and/or a deposition process on the sample using the particle beam.

According to an embodiment, at least a portion of the test structure and at least a portion of the sample have an identical material composition.

According to a further aspect, there is provided a method for providing a test structure in an apparatus for analysing and/or processing a sample with a particle beam, wherein the apparatus comprises:
a providing unit being configured for providing the particle beam; and the test structure attached to the providing unit;

wherein the method comprises:
implementing an etching process and/or a deposition process on the test structure using the particle beam.

According to a further aspect, there is provided a method for analysing and/or processing a sample with a particle beam using an apparatus, comprising:
performing the method as described above;
detecting an interaction of the particle beam with the test structure; and
determining at least one current operating parameter and/or process parameter of the apparatus depending on the interaction detected.

This may be followed by analysing and/or processing the sample depending on the determined at least one current operating parameter and/or process parameter of the apparatus.

All aspects and embodiments as described above may be combined as deemed fit by the skilled person.

“A(n)” in the present case should not necessarily be understood to be restrictive to exactly one element. Rather, a plurality of elements, such as, for example, two, three or more, can also be provided. Any other numeral used here, too, should not be understood to the effect that there is a restriction to exactly the stated number of elements. Rather, numerical deviations upwards and downwards are possible, unless indicated to the contrary.

Further possible implementations of the invention also comprise not explicitly mentioned combinations of any features or embodiments that are described above or below with respect to the exemplary embodiments. In this case, a person skilled in the art will also add individual aspects as improvements or supplementations to the respective basic form of the invention.

Further advantageous configurations and aspects of the invention are the subject matter of the dependent claims and also of the working examples of the invention described hereinafter. The invention is elucidated in detail hereinafter by preferred embodiments with reference to the appended figures.

### BRIEF DESCRIPTION OF DRAWINGS

FIG. 1 shows a schematic view of a first embodiment of an apparatus for analysing and/or processing a sample with a particle beam;

FIG. 2 shows a schematic view of a second embodiment of an apparatus for analysing and/or processing a sample with a particle beam;

FIG. 3 shows a schematic view of a shielding element having multiple test structures;

FIG. 4 shows a schematic view of an embodiment of a further apparatus for analysing and/or processing a sample with a particle beam;

FIG. 5 shows a schematic view of a vibrating element for determining a deposition rate or an etch rate;

FIG. 6 shows an illustrative diagram having two measurement curves as examples of a detected vibration property;

FIG. 7 shows a schematic view of a working example of a holding element having a shielding element and an exciter unit;

FIG. 8 shows a schematic view of a second embodiment of the further apparatus for analysing and/or processing a sample with a particle beam;

FIG. 9 shows, in two schematic diagrams, determining of a residence time of a process gas at a surface;

FIG. 10 shows a schematic block diagram of a working example of a first method of analysing and/or processing a sample;

FIG. 11 shows a schematic block diagram of a working example of a second method of analysing and/or processing a sample;

FIG. 12 shows an example of a test structure for verifying a resolution of an electron microscope; and

FIG. 13 shows a schematic view of a further embodiment of an apparatus for analysing and/or processing a sample with a particle beam.

### DETAILED DESCRIPTION

Unless indicated to the contrary, elements that are the same or functionally the same have been given the same reference signs in the figures. It should also be noted that the illustrations in the figures are not necessarily true to scale.

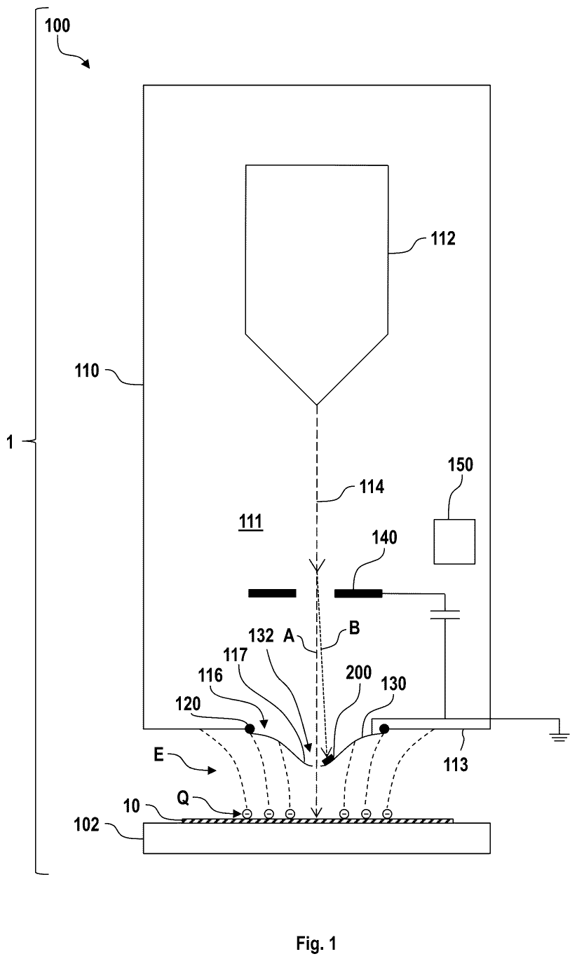

FIG. 1 shows a schematic view of a first working example of an apparatus 100 for analysing and/or processing a sample 10 with a particle beam 114. The apparatus 100 is preferably arranged in a vacuum housing (not illustrated). The apparatus 100 comprises a providing unit 110 for providing the particle beam 114 and a sample stage 102 for holding the sample 10, said sample stage being arranged below the providing unit 110. It should be noted that the sample 10 is not part of the apparatus 100. The apparatus 100 and the sample 10 together form a system 1.

The sample 10 is for example a lithography mask having a feature size in the range of 10 nm-10 μm. This can be for example a transmissive lithography mask for DUV lithography (DUV: “deep ultraviolet”, operating light wavelengths in the range from 30-250 nm) or a reflective lithography mask for EUV lithography (EUV: “extreme ultraviolet”, operating light wavelengths in the range from 1-30 nm). The processing operations that are implemented on the sample 10 with the apparatus 100 include, for example, etching processes, in which a material is locally removed from the surface of the sample 10, deposition processes, in which a material is locally applied to the surface of the sample 10, and/or similar locally activated processes, such as forming a passivation layer or compacting a layer.

The providing unit 110 comprises in particular a particle beam generating unit 112, which generates the particle beam 114. The particle beam 114 consists of charged particles, for example of ions or of electrons. The example of FIG. 1 involves an electron beam. The providing unit 110 is therefore also referred to as an electron column (or electron beam column), wherein the apparatus 100 forms a scanning electron microscope, for example. The electron beam 114 is guided by use of beam guiding elements (not shown in FIG. 1). This is also referred to as an electron optical unit. Furthermore, the electron column 110 may comprise detectors (not shown in FIG. 1) for detecting an electron signal originating from backscattered electrons and/or from secondary electrons, for example.

The electron column 110 has a dedicated vacuum housing 113, which is evacuated to a residual gas pressure of 10⁻⁶mbar-10⁻⁸ mbar, for example. An opening 116 for the electron beam 114 is arranged at the underside. The opening 116 is covered by a shielding element 130 which is secured on the opening 116 by use of a holding element 120 which may attach to the housing 113. The holding element 120 comprises, for example, multiple screws in order to screw the shielding element to the electron column 110. The shielding element 130 and/or the holding element 120 may form part of the providing unit 110 to define an inner volume 111 (which may be evacuated to a residual gas pressure of 10⁻⁶mbar-10⁻⁸ mbar, for example, and/or which may be partially or fully arranged inside the vacuum housing 113) thereof.

The shielding element 130 is in two-dimensional form and comprises an electrically conductive material. The shielding element is preferably formed from a material which is inert with respect to the process gas atmosphere and which has only a minor effect, if any, on the processes envisaged. By way of example, the shielding element 130 is formed from gold or nickel. The shielding element 130 has a convex section 117 with respect to the sample stage 102 and the sample 10. The convex section 117 curves in the direction of the sample stage 102. The convex section 117 has a through opening 132 for the particle beam 114 to pass through. The through opening 132 comprises in particular a point of the convex section 117 which is closest to the sample stage 102. The distance between the shielding element 130 and the sample stage 102 or the sample 10 is thus at its smallest in the region of the through opening 132. The distance between the through opening 132 and the sample 10 is preferably between 5 μm-30 μm, preferably 10 μm, during operation of the apparatus 100. Preferably, the sample stage 102 has a positioning unit (not shown), by means of which a distance between the sample stage 102 and the electron column 110 is settable.

The shielding unit 130 may have a planar region from which the convex section 117 projects. The planar region preferably extends in a radial direction from an upper end of the convex section 117. A transition section in which the planar region merges into the convex section 117 may have a concave curvature. The shielding element 130 is secured at the opening 116 of the electron column 110 for example at an outer edge of the planar region.

Earth potential is applied to the shielding element 130 in this example. This means that the shielding element 130 is set up to shield an electrical field E (in other embodiments a magnetic field). In order to illustrate this, FIG. 1 shows, by way of example, charges Q that are present on the sample 10 and generate an electric field E. Particularly in the case of samples 10 which are electrically non-conductive or only slightly conductive (at least in sections), when the electron beam 114 is incident on the sample 10, charging of the sample 10 and thus the formation of the electric field E occur, as illustrated in FIG. 1. FIG. 1 shows, by way of example, negative charges Q that arise as a result of the incidence of the electron beam 114. In other embodiments, the electrical and/or magnetic field may also originate from the electron column 110 itself or be formed therein or generated therein.

A test structure 200 is disposed on the shielding element 130, for example. The test structure 200 may be arranged on the inside surface of the shielding element 130 so as to be arranged inside the inner volume 111 of the providing unit 110. The test structure 200 may be attached to the shielding element 130. In one embodiment said attachment is formed as a cohesive bond. In another embodiment said attachment is provided by the test structure 200 being formed as one piece with the shielding element 130. For example, the test structure 200 may be defined by an inner surface of the shielding element 130.

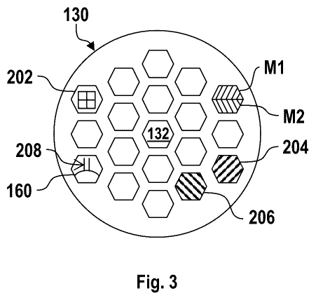

The test structure 200 may be formed as elucidated in detail hereinafter with reference to FIG. 3 and may provide one or more functions. Examples of such functions are a dissolution test by use of a dissolution test pattern, a contrast test by use of a contrast pattern (especially a material contrast and/or a secondary electron contrast at at least one edge), or a process test by use of an area of a particular material for which the respective process is to be tested. Possible alternative terms to “testing” include “adjusting”, c alibrating” or “running in”.

Additionally disposed between the beam generation unit 112 and the shielding element 130 may be an aligning unit 140 which, in this example, is designed as a jet deflection unit. The aligning unit 140 is set up to deflect the electron beam 114 either onto the through opening 132 or onto the test structure 200. For this purpose, the aligning unit 140 is connected to a voltage source that provides a voltage for generating a suitable electrical field for deflection of the particle beam 114. In FIG. 1, A indicates the beam pathway when the aligning unit 140 directs the electron beam 114 onto the passage opening 132, and B indicates the beam pathway when the aligning unit 140 directs the electron beam 114 onto the test structure 200.

Changeover from beam pathway A to beam pathway B or vice versa can be effected within a short period of time which may, for example, be between 1 us up to 1 s. This means that, even during the course of an analysis or processing operation on the sample 10, the electron beam 114 can regularly be directed onto the test structure 200 in order, for example, to monitor a particular beam property or process property.

If the electron beam 114 is directed onto the test structure 200, an interaction takes place between the electron beam 114 and the test structure 200. This interaction can be detected with a detector, as already stated at the outset. The aligning unit 140 may be utilized, for example, in a twin function as a detector as well, which detects backscattered electrons or secondary electrons. Preferably, further detectors are provided, which are arranged, for example, at further spatial angles in relation to the test structure 200 and/or which are sensitive to electrons of different energy. FIG. 1, for reasons of clarity, does not show any additional detectors.

The apparatus 100 additionally comprises a determining unit 150 set up to determine an operating parameter and/or a process parameter of the apparatus 100 depending on the interaction detected. The determining unit 150 is set up to receive corresponding measurement data relating to the interaction (for reasons of clarity, FIG. 1 does not show any data wires or the like). The measurement data may include, for example, a scanning electron microscope image of the test structure, which can be used to ascertain a current resolution of the electron microscope, which is an example of a current operating parameter of the apparatus 100.

Since the test structure 200 is not disruptive during the operation of the apparatus 100 for analysing and/or processing the sample 10, it can remain in the vacuum housing of the apparatus 100 when the analysis or processing of the sample 10 is being conducted. It is thus possible to determine the current operating parameter and/or process parameter in situ, i.e. essentially under the same conditions under which the subsequent analysis and/or processing is implemented. It is thus possible to ensure that the operating parameters and/or process parameters have the desired value or are adjusted such that successful analysis and/or processing of the sample 10 is possible.

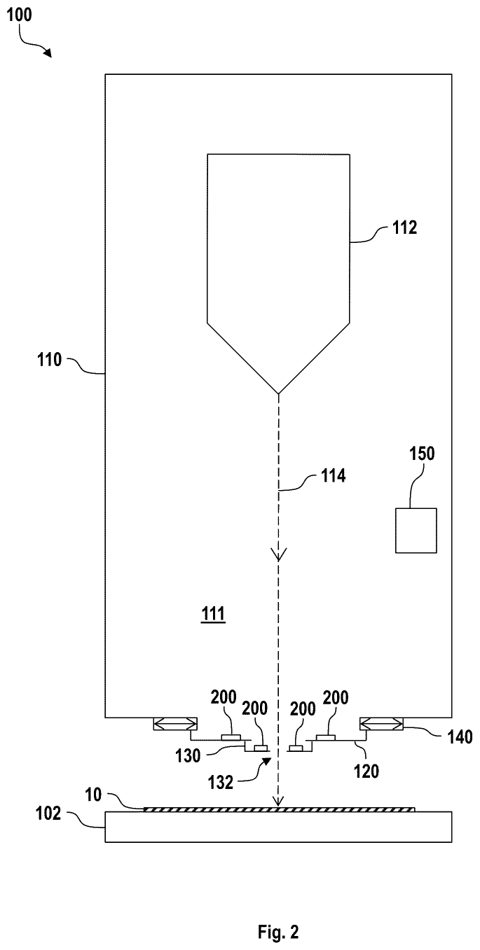

FIG. 2 shows a schematic view of a second embodiment of an apparatus 100 for analysing and/or processing a sample 10 with a particle beam 114. The apparatus 100 of FIG. 2 is identical to that of FIG. 1 apart from the differences elucidated hereinafter. In FIG. 2, the holding element 120 is in two-dimensional form and is disposed on the providing unit 110 by use of an aligning unit 140 in the form of a moving unit. The moving unit 140 is set up to move the holding element 120, and with it the shielding element 130 secured to the holding element 120, especially in a direction parallel to a sample surface of the sample 10 and essentially at right angles to the particle beam 114.

The shielding element 130 is secured on the holding element 120 (for example in a one-part or one-piece manner), and in this example is in flat rather than convex form, although it is also possible to use the convex-shaped shielding element 130 of FIG. 1. The earthing of the shielding element 130 is not shown in FIG. 2 for reasons of clarity. In this working example, the holding element is manufactured, for example, from nickel-silver.

In this example, two test structures 200 are also disposed in each case on the holding element 120 and on the shielding element 130, which preferably each provide different functions, i.e. are of different construction, as elucidated in detail hereinafter, for example, with reference to FIG. 3.

The aligning unit 140 allows the holding element 120 together with the shielding element 130 and the test structures 200 to be moved relative to the particle beam 114 such that the particle beam 114 does not exit through the passage opening 132, but optionally radiates onto one of the test structures 200. In other words, the respective test structure 200 is pushed under the particle beam 114. It is thus also possible using the apparatus 100 of FIG. 2 to ascertain current operating parameters and/or process parameters using the test structures 200.

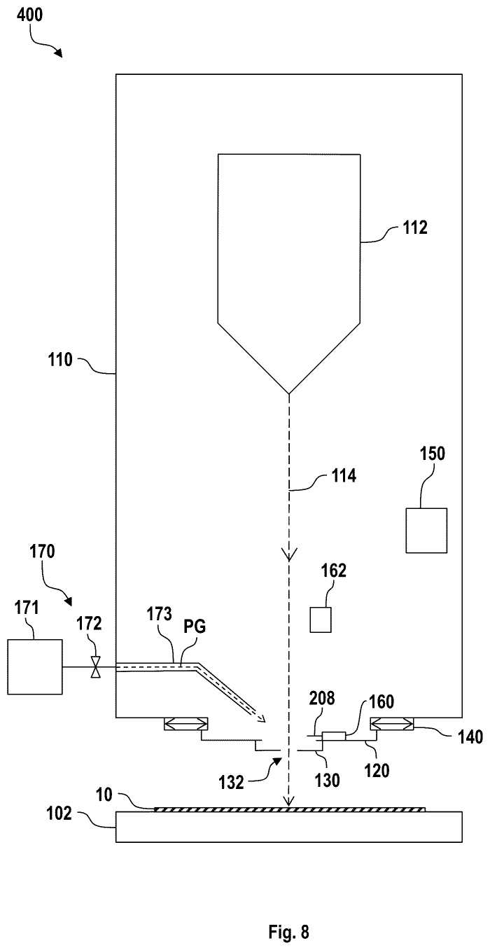

It should be noted that the apparatuses 100 of FIG. 1 and FIG. 2 may also be combined with one another. In addition, these may each have a process gas providing unit 170 as elucidated, for example, with reference to FIG. 8.

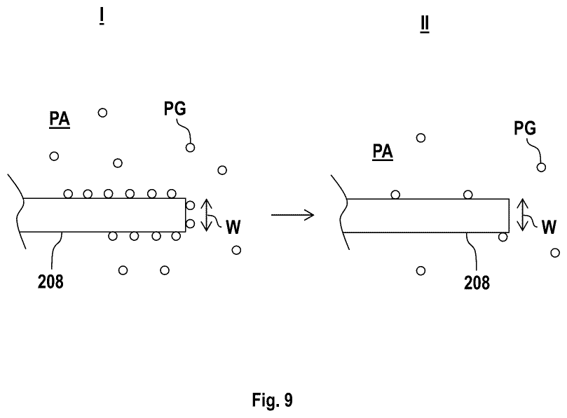

FIG. 3 shows a schematic top view of a shielding element 130 with multiple test structures 202, 204, 206, 208, M1, M2. The shielding element 130 here has a mesh structure with multiple passage openings 132, of which only the middle passage opening is given a reference numeral. The shielding element 130 has, for example, a convex form as shown in FIG. 1, with the middle passage opening 132 being the lowest (the closest to the sample 10). The further passage openings 132 may also be utilized for passage of the particle beam 114 (see FIG. 1 or 2). In this example, however, these serve especially as a through opening for process gas PG (see FIG. 8 or 9) when the process gas PG, as described with reference to FIG. 8, is fed in from the top (see FIG. 8).

Test structures 202, 204, 206, 208, M1, M2 are disposed in or at some of the through openings 132 that are close to the edge for provision of different functions for determining current operating parameters and/or process parameters.

The structure 202 has, for example, a spatial resolution at frequencies between 1/μm-1000/μm. The structure 202 may, for example, comprise a topographic structure and/or may comprise a structured arrangement of different materials. In one example, the structure comprises gold clusters or gold nanoparticles on a surface, for example on a carbon substrate (see also FIG. 12), where the gold clusters for example have sizes between 2.5 nm-500 nm.

The test structure 203 consists of at least two different materials M1, M2 and hence provides a material contrast. The materials are especially particular materials M1, M2 that are selected such that a particular material contrast is provided, with the aid of which a detector or multiple detectors of the device 100 may be calibratable. Preferably, the test structure 203 consists of more than two materials in order to provide correspondingly different material contrasts. Examples of possible materials M1, M2 are C, Cr, Mo, Si, Ta, Ru, W, Rh, Pt, Re and Au, with the possibility of different combinations of two or more than two of these materials M1, M2. The aforementioned materials are conductive materials. It is also possible to use nonconductive materials, such as quartz, sapphire or the like. In preferred embodiments, two or more materials M1, M2 that have a maximum difference in their atomic number are combined.

In addition, there are two predetermined areas 204, 206 which are intended and suitable for implementation of particle beam-induced deposition processes and/or particle beam-induced etching processes. The predetermined areas 204, 206 preferably consist of the same material as the material of the sample 10 to be etched (see FIG. 1 or 2) or the material of the sample 10 at the site where a deposition process is to be conducted. Examples of these are Cr, MoSi, SiN, SiON, Ta, TaN, TaBN, Ru or else quartz.

If the material M1, M2 from which the test structure 203 and/or the predetermined areas 204, 206 are formed is electrically insulating, it is additionally possible to provide a shielding unit for the test structure 203 and the predetermined areas 204, 206 (not shown). This shielding unit would shield an electrical field that originates from charging of the test structure 203 and/or of the predetermined area 204, 206 by the incident particle beam counter to the beam direction, such that electrostatic effects caused by charging can be avoided or reduced. This increases reliability of the results that are determined using the test structure 203 and/or the predetermined area 204, 206.

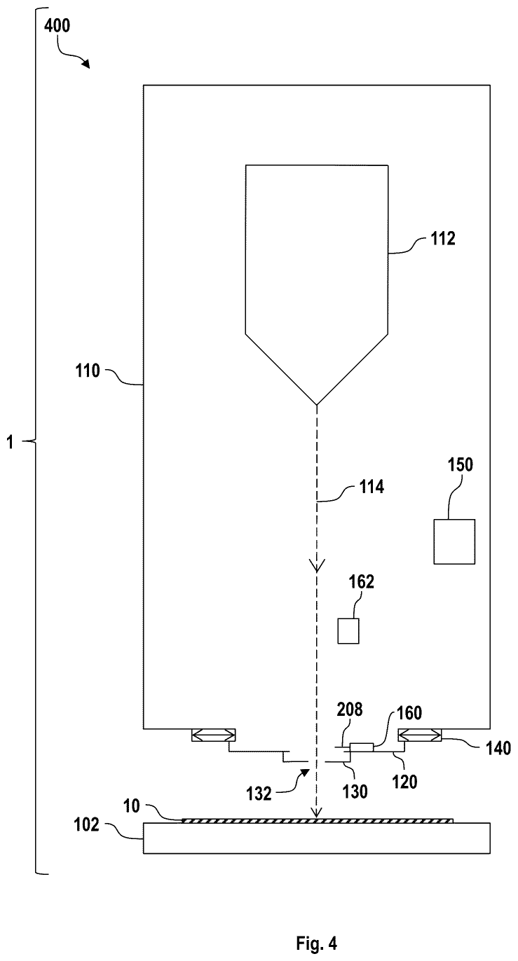

In addition, the shielding element 130, in one of the through openings 132, has an arrangement comprising an exciter unit 160 and a vibrating element 208. The vibrating element 208 here comprises two individual cantilevers that can independently perform vibrations. The cantilevers may consist of different materials and/or have different geometries. The exciter unit 160 is set up to induce the vibrating element 208 to mechanically vibrate. The exciter unit 160 comprises, for example, a piezoelectric actuator. The exciter unit 160 may simultaneously serve as detecting unit set up to detect a vibration property of the vibration performed by the vibrating element 208. On the basis of the vibration property detected, it is possible to conclude further operating parameters and/or process parameters. The function thus provided is described in detail with reference to FIGS. 4-9.

If the above-described shielding element 130 is used in one of the devices 100 of FIG. 1 or FIG. 2, the particle beam 114, using the aligning unit 140, may be directed selectively onto any of structures 202, 203, 204, 206, 208, in order to determine corresponding operating parameters and/or process parameters of the apparatus 100 depending on the detected interaction of the particle beam 114 with the particular structure 202, 203, 204, 206, 208.

It should be noted that the shielding element 130, in embodiments, may have only individual structures 202, 203, 204, 206, 208, M1, M2 described and/or may have further structures of this kind. If the shielding element 130 includes the vibrating element 208 and the exciter unit 160, and the apparatus 100, 400 additionally has a detecting unit 162 (see FIG. 4 or 8) for detecting a vibration property of the vibrating element 208 that vibrates, the apparatus 100, 400 combines the features and functions of the apparatuses 100 of FIG. 1 or 2 with those of the apparatus 400 of FIG. 4 or 8.

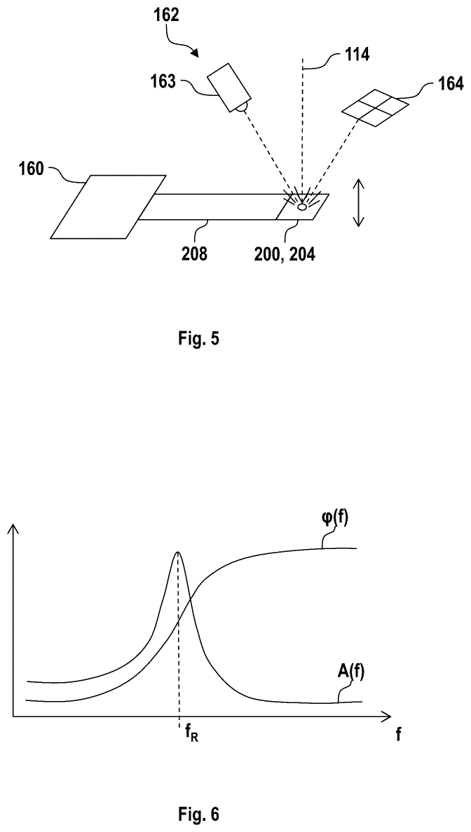

FIG. 4 shows a schematic view of an embodiment of an apparatus 400 for analysing and/or processing a sample 10 with a particle beam 114. The basic construction of the apparatus 400 corresponds to that of the apparatuses of FIG. 1 and FIG. 2. A test structure 200, as elucidated with reference to FIG. 1 or 2, is not possessed by the apparatus 400 in this example; instead, the apparatus 400 additionally has an exciter unit 160 set up to induce a vibration element 208 disposed on the exciter unit 160 to mechanically vibrate. In addition, an optical detecting unit 162 is disposed above the vibrating element 208, which detects a vibration property A(f), φ(f) (see FIG. 6) of the vibrating element 208 on the basis of optical measurements and outputs it, for example, to the determining unit 150. The more accurate mode of function of the exciter unit 160 of the vibrating element 208 and of the detection unit 162 is elucidated in detail hereinafter with reference to FIGS. 5 and 6.

On the basis of the detected vibration property A(f), φ(f), it is possible to determine an operating parameter and/or a process parameter of the apparatus 400, for example a partial pressure of a process gas, a composition of a process atmosphere, an etch rate and/or a deposition rate. This too is elucidated in detail hereinafter.

It should be noted that the features described above with reference to the apparatus 400 may also be integrated together with the features of the apparatus 100 of FIGS. 1 and/or 2. For example, the aligning unit 140 may be designed as elucidated with reference to FIG. 1, or an additional aligning unit 140 is provided. In addition, the aligning unit 140 may also be dispensed with entirely in embodiments.

FIG. 5 shows a schematic view of a vibrating element 208 which is utilizable for determining a deposition rate or an etch rate. This is, for example, the vibrating element 208 which is present in the apparatus 400 of FIG. 4 and/or disposed on the shielding element 130 of FIG. 3. An exciter unit 160 is set up to induce the vibrating element 208 to perform mechanical vibrations W. The vibrating element 208 takes the form of a cantilever by way of example. The cantilever 208 has a predetermined area 204 at a front end, which consists of chromium, for example, and is intended to perform a particle beam-induced etching process.

A detecting unit 162 for detecting a vibration property A(f), φ(f) (see FIG. 6) comprises a laser 163 and a photodetector 164. This measuring principle is known from scanning electron microscopes.

By radiating the particle beam 114 onto the predetermined area 204 (another embodiment of a test structure 200, for example), it is possible to trigger an etching process, especially when a precursor gas is present around the cantilever 208 in the process atmosphere, which can be converted by the incidence of the particle beam 114 directly or indirectly to an active species which then in turn reacts chemically with atoms of the predetermined area 204 to form a volatile reactant. Such an etching process especially reduces the mass of the cantilever 208, which can be detected by a change in the detected vibration property A(f), φ(f). In other words, the change in the detected vibration property A(f), φ(f) can be used to conclude the decrease in mass of the cantilever 208 and hence the current etch rate in the etching process. For deposition processes in which material is deposited on the cantilever 208, this can be utilized correspondingly for determining a current deposition rate.

FIG. 6 shows an illustrative diagram having two measurement curves as examples of a detected vibration property A(f), φ(f). This example concerns the amplitude A(f) of the vibration being performed by the excited element 120, 130, 208 (see FIGS. 1-5) as a function of the excitation frequency f, and a phase shift φ(f) between the exciter vibration and the vibration excited. The horizontal axis shows the excitation frequency f and the vertical axis shows the deflection based on the curve A(f) and the phase shift based on the curve φ(f). In the case of the resonance frequency f_{R}, the element induced to vibrate has an amplitude maximum. The example illustrated shows a schematic of the situation for a cantilever with a free end. Other vibrating systems may behave differently. Especially vibrating systems having more degrees of freedom that perform two-dimensional or three-dimensional vibrations may show a different behaviour here, especially more complex behaviour.

If, as elucidated above with reference to FIG. 5, there is a change in the mass of the cantilever 208, this has the effect, for example, of a shift in the resonance frequency f_{R}. The change in mass can be concluded from the change in resonance frequency f_{R}.

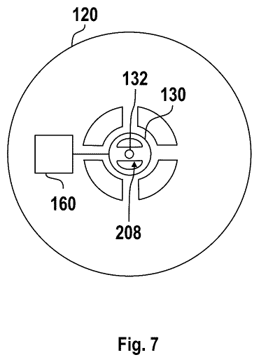

FIG. 7 shows a schematic view of a working example of a holding element 120 having a shielding element 130 and an exciter unit 160. In this example, the exciter unit 160 is set up to induce the shielding element 130 to mechanically vibrate, with the shielding element 130 being specifically adapted for this function. This means that the shielding element 130, apart from the shielding effect, additionally has the function of a vibrating element 208. For example, the middle bar of the shielding element 130 in which the through opening 132 is present serves as a vibrating element 208 having two fixed ends. The exciter unit 160 is secured on the holding element 120. The holding element 120 in this example has further openings for passage of process gas PG fed in from the top (see FIGS. 8 and 9). These openings are optional. The vibration property A(f), φ(f) (see FIG. 6) of the vibrating element 208 may be detected optically, as described, for example, with reference to FIG. 5.

FIG. 8 shows a schematic view of a second embodiment of the further apparatus 400 for analysing and/or processing a sample 10 with a particle beam 114. The apparatus 400 has the same features as the apparatus 400 elucidated with reference to FIG. 4. In addition, the apparatus 400 has a process gas providing unit 170. This comprises a process gas reservoir 171 containing, for example, the process gas PG in a solid or liquid state at low temperature, or else in a highly compressed gaseous state under high pressure. The process gas PG can be fed via a conduit 173 from the reservoir 171 into the particle beam providing unit 110, especially into a region directly above the shielding element 130 which preferably has a multitude of openings, as shown in FIG. 3, for example, such that the process gas PG can flow toward the sample 10. This feeding of the process gas PG can be referred to as feeding “from the top”. Alternatively, it is possible to feed the process gas PG to the sample 10 from the side (not shown). A valve 172 can be utilized for regulation of the process gas flow.

The process gas PG may comprise a mixture of different gas species, with gas species being understood to mean both pure elements such as H₂, He, O₂, N₂ and the like and composite gases such as CH₄, NH₃, H₂O, SiH₄ and the like. A respective partial pressure of a respective gas species is preferably adjustable via the supply and/or removal of the respective gas species, especially via valves 172 and vacuum pumps (not shown).

It should be noted that the process gas providing unit 170 shown in FIG. 8 is also usable with the apparatuses 100 of FIG. 1 or 2.

FIG. 9 shows, in two schematic illustrations, determining of a dwell time of a process gas PG at a surface of a vibrating element 208 which takes the form of a cantilever and which is inducible to mechanically vibrate by use of an exciter unit 160 (not shown) (see FIG. 3, 4, 5, 7, 8). A detecting unit 162 (not shown) (see FIG. 3, 4, 5, 7) is set up to detect a vibration property A(f), φ(f) (see FIG. 6). In the first state I, the process atmosphere PA is relatively densely populated with the process gas PG. Therefore, individual molecules of the process gas PG are adsorbed in a dense layer (monolayer). Thus, the mass of the cantilever 208 is increased by the mass of this monolayer, and a particular resonance frequency f_{R} (see FIG. 6) is established. In the second state II, for example, the gas supply of the process gas PG was ended and the process atmosphere PA becomes thinner. The molecules adsorbed on the cantilever 208 are therefore likewise volatilized, such that the mass adsorbed decreases, resulting in an altered resonance frequency f_{R} compared to the state I. By an observation of the change in resonance frequency f_{R} with time, it is possible, for example, to ascertain the dwell time of the process gas PG at the cantilever 208. It should be noted that, rather than the resonance frequency f_{R}, it is also possible to detect and evaluate other vibration properties for determination of this process parameter and/or other operating parameters or process parameters.

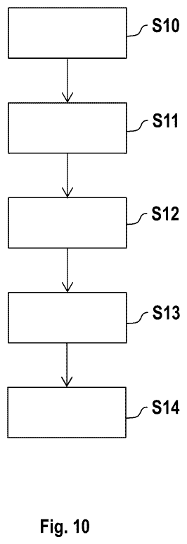

FIG. 10 shows a schematic block diagram of a working example of a first method of analysing and/or processing a sample 10 (see FIG. 1, 2, 4 or 8) by means of an analysis and/or processing operation in an apparatus 100, 400. In a step S10, a test structure 200 (see FIGS. 1-3) is provided in a vacuum housing of the apparatus 100, 400. In a second step S11, the vacuum housing is evacuated for provision of a process atmosphere PA (see FIG. 9) for performance of the analysis and/or processing operation. Optionally, this step comprises the supply of one or more process gases PG (see FIG. 8 or 9). In a third step S12, the particle beam 114 (see FIG. 1, 2, 4, 5, 8) is radiated onto the test structure 200. This step especially comprises aligning the particle beam 114 onto the test structure 200, for example by use of an aligning unit 140. In a fourth step S13, an interaction of the particle beam 114 with the test structure 200 is detected. The interaction is especially detected by use of a detector, such as a backscattered electron detector and/or a secondary electron detector. It is alternatively possible to use other detectors, for example optical detectors. If the apparatus 100, 400 has an exciter unit 160 (see FIG. 3, 4, 5, 7) set up to induce a mechanical vibration W (see FIG. 5) of the holding element 120 (see FIG. 1, 2, 4, 8), shielding element 130 (see FIG. 1, 2, 4, 8) and/or vibrating element 208 (see FIG. 3, 4, 5, 7, 8), and a detecting unit 162 (see FIG. 4, 5, 8) is set up to detect a vibration property A(f), φ(f) (see FIG. 6), this arrangement forms a combination of the test structure and the detector. In a fifth step S14, at least one current operating parameter of the apparatus 100, 400 and/or process parameter for the analysis and/or processing operation is determined depending on the interaction detected. In this case, in particular, measurement data that are detected by the respective detector and describe the interaction of the particle beam 114 with the test structure 200 are evaluated by use of one or more physical and/or mathematical models.

This method may be implemented with any of the apparatuses 100, 400 of FIG. 1, 2, 4 or 8. The sample 10 is especially a lithography mask. The test structure 200 especially has identical or similar materials and/or structures to the lithography mask.

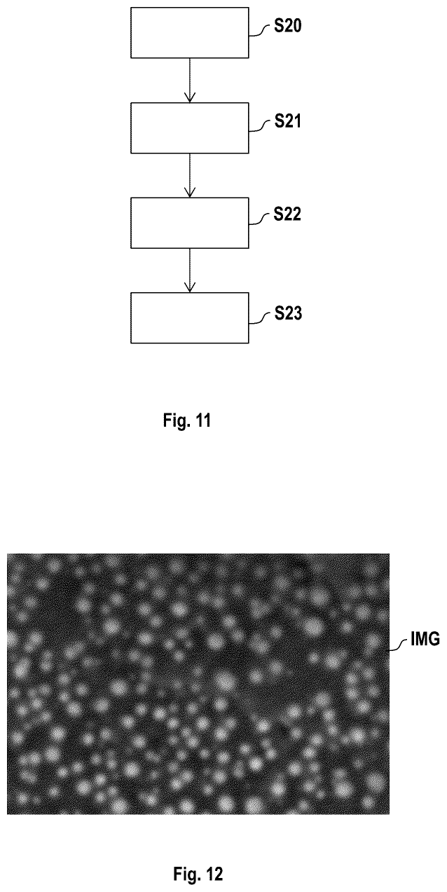

FIG. 11 shows a schematic block diagram of a working example of a second method of analysing and/or processing a sample 10 (see FIG. 1, 2, 4, 8) with a particle beam 114 (see FIG. 1, 2, 4, 8) by means of an analysis and/or processing operation in an apparatus 100, 400. The apparatus 100, 400 has a shielding element 130 (see FIG. 1, 2, 4, 7, 8), held by a holding element 120 (see FIG. 1, 2, 4, 7, 8), for shielding an electrical field E (see FIG. 1) which is generated by charges Q accumulated on the sample 10 (see FIG. 1). Moreover, the shielding element 130 has a passage opening 132 (see FIGS. 1-4, 7, 8) for passage of the particle beam 114 onto the sample 10. In a first step S20 of the method, a vacuum housing of the apparatus 100, 400 is evacuated for provision of a process atmosphere PA (see FIG. 9) for performance of the analysis and/or processing operation. Optionally, this step comprises the supply of one or more process gases PG (see FIG. 8 or 9). In a second step 21, the holding element 120, the shielding element 130 and/or a vibrating element 208 disposed on the holding element 120 or the shielding element 130 (see FIG. 4, 5, 7, 8, 9) is induced to perform mechanical vibrations W (see FIG. 5). In a third step S22, a vibration property A(f), φ(f) (see FIG. 6) of the holding element 120, shielding element 130 and/or vibrating element 208 that has been induced to vibrate is detected. The vibration property A(f), φ(f) is especially detected by use of an optical detector and/or by use of an electrostrictive sensor element, such as a piezo crystal. In a fourth step S23, at least one current operating parameter and/or process parameter of the apparatus 100, 400 is determined depending on the vibration property A(f), φ(f) detected. In this case, in particular, measurement data that are detected by the respective detector and describe the interaction of the particle beam 114 with the test structure 200 are evaluated by use of one or more physical and/or mathematical models.

This method may be implemented with any of the apparatuses 100, 400 of FIG. 1, 2, 4 or 8. The sample 10 is especially a lithography mask. The holding element 120, the shielding element 130 and/or the vibrating element 208 preferably have a test structure 200 (see FIGS. 1-3).

The methods described with reference to FIG. 10 and FIG. 11 are especially combinable. Both methods are suitable for monitoring and/or optimizing an analysis and/or processing operation of a sample 10 by use of an apparatus 100, 400, in that a respectively optimal adjustment of the operating parameters and/or process parameters is undertaken.

FIG. 12 shows an example of an electron micrograph IMG of a test structure 200 (see FIGS. 1-3) for verifying a resolution of an electron microscope or else for calibrating the electron microscope.

The test structure 200 used is gold nanoparticles on carbon. The gold nanoparticles in the image IMG stand out in a light colour against the carbon substrate.

On the basis of the image IMG, it is possible, for example, to determine the resolution achieved with the electron microscope. Advantageously, for this purpose, a size distribution of the gold nanoparticles is known, for example from the production process for production of the test structure and/or by sampling the test structure with a scanning electron microscope or the like. In addition, on the basis of the image IMG, a beam profile of the electron beam can be ascertained by analysing an intensity progression along an edge that results, for example, from a gold nanoparticle.

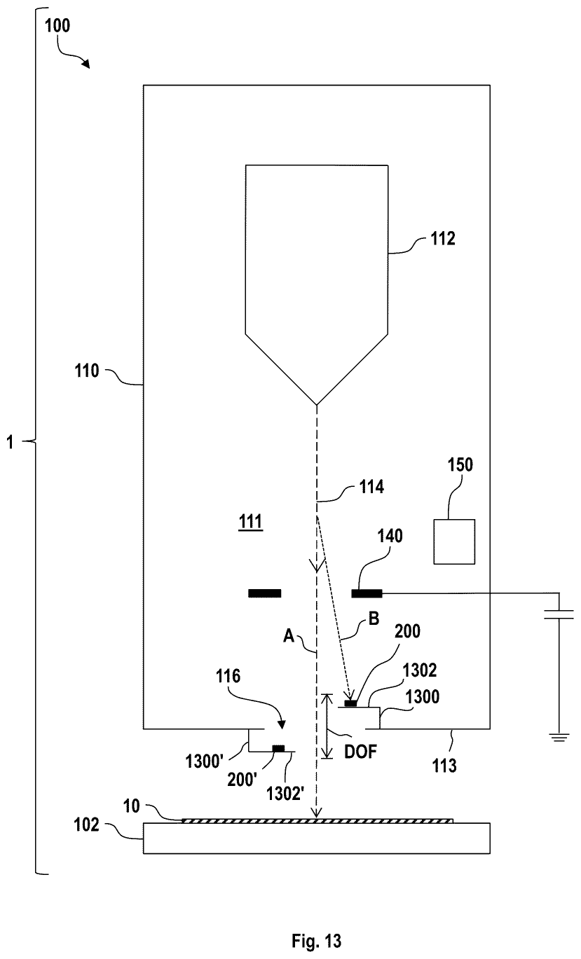

In the apparatus 100 of FIG. 13, an arm 1300 may be provided which attaches to the housing 113 of the providing unit 110. The arm 1300 may hold a horizontal platform 1302. The arm 1300 and/or the platform 1302 may be integrally formed with the housing 113. In other embodiments, the platform 1302 is attached directly to (and/or integrally formed with) the housing 113 or any other part of the providing unit 110. The arm 1300 may extend (at least partially) in the vertical direction as shown in FIG. 13.

A test structure 200 (as for example described in any of the above embodiments) may be arranged on the platform 1302 so as to face towards the beam generating unit 112. The test structure 200 may be attached to the platform 1302 which includes the case where the test structure 200 is integrally formed with the platform 1302 (for example, the test structure 200 is the surface of the platform 1302). So, generally speaking, the test structure 200 may be attached directly or indirectly (i.e. via other components) to the providing unit 110 which may include the case where the test structure is formed integrally with the providing unit 110 or a component thereof. Attachment may be effected in a force-locking, form-fitting and/or cohesive manner (as defined above).

The apparatus 100 is configured for implementing an etching process and/or a deposition process on the test structure 200 using the particle beam 114. A process gas supply unit 170 as shown in FIG. 8 may be provided to supply process gas PG (see FIG. 8) to the test structure 200 for etching the test structure 200 and deposition of material thereon. To this end, the particle beam 114 may interact with the process gas PG. The gas supply unit 170 may also deliver process gas to the sample 10 for etching the sample 10 and/or depositing material thereon under the action of the particle beam 114.

All embodiments described above apply to the embodiment of FIG. 13 and vice versa. For example, the platform 1302 may form, together with the test structure 200, a vibrating element 208.

The test structure 200 as arranged on the platform 1302 (right hand side of FIG. 13) is arranged inside the inner volume 111 enclosed by the housing 113. For example, the arm 1300 is connected to an inside portion of the housing 113. The platform 1302 may extend horizontally above the opening 116.

On the other hand, in a further embodiment shown on the left side of FIG. 13, the test structure 200′ is arranged outside of the inner volume 111. For example, the arm 1300′ is attached to an outside portion of the housing 113. The platform 1302′ may extend horizontally below the opening 116.

More generally and as shown in FIG. 13, the test structure 200 may be arranged inside (when looking along beam A) or adjacent to the opening 116 for the particle beam to exit the providing unit 110.

Reference numeral DOF denotes a depth of field (DOF) of the providing unit 110 (in particular, a DOF of the electron microscope comprised by said providing unit 110). The DOF is the distance between the nearest and the furthest objects that are in acceptably sharp focus. As can be seen, the DOF may be designed so as to include the test structure 200. The DOF may be designed to include also the sample 10. Thus both (sample 10 and test structure 200) may be imaged in sharp focus. The DOF may be up to 100, up to 10 or up to 1 micrometer, and/or at least 1, 10 or 100 micrometers, for example.

Once the test structure 200 has been etched or material deposited thereon, an image (or any other interaction) of the etched or deposited structure (not shown in FIG. 13) may be taken using the particle beam 114. Based on said image or other interaction, the determining unit 150 determines a current operating parameter or process parameter. For example, the determining unit 150 determines a telecentricity of, e.g., the providing unit 110, in particular of the electron microscope.

Although the present invention has been described with reference to working examples, it is modifiable in various ways.

### LIST OF REFERENCE SIGNS

1 System
10 Sample
100 Apparatus
102 Sample stage
110 Providing unit
111 Inner volume
112 Beam generating unit
113 Housing
114 Particle beam
116 Opening
117 Convex section
120 Holding element
130 Shielding element
132 Through opening
140 Aligning unit
150 Determining unit
160 Exciter unit
162 Acquisition unit
163 Laser
164 Photodetector
170 Process gas providing unit
171 Process gas reservoir
172 Valve
173 Line
200 Test structure
202 Structure
203 Structure
204 Predetermined area
206 Predetermined area
208 Vibrating element
400 Apparatus
1300 Arm
1302 Platform
φ(f) Phase (vibration property)
A Beam pathway
A(f) Amplitude (vibration property)
B Beam pathway
DOF Depth of field
E Field lines
f Frequency
f_{R} Resonance frequency
IMG Electron micrograph
M1 Material
M2 Material
PA Process atmosphere
PG Process gas
Q Charges
S10 Method step
S11 Method step
S12 Method step
S13 Method step
S14 Method step
S20 Method step
S21 Method step
S22 Method step
S23 Method step
W Vibration

What is claimed is:

1. An apparatus for analysing and/or processing a sample with a particle beam, comprising:
a providing unit for providing the particle beam, the providing unit having an opening for the particle beam to pass through to the sample; and
a test structure attached to the providing unit, the test structure being arranged inside or adjacent to the opening of the providing unit;
wherein the apparatus is configured for implementing an etching process and/or a deposition process on the test structure using the particle beam.

2. The apparatus of claim 1, further comprising a determining unit for determining at least one current operating parameter and/or process parameter of the apparatus depending on an interaction of the particle beam with the test structure on which the etching process and/or a deposition process has been implemented.

3. The apparatus of claim 1, wherein the test structure is arranged inside an inner volume defined by the providing unit.

4. The apparatus of claim 1, further comprising an electron microscope, wherein the test structure is arranged within a depth of field of the electron microscope.

5. The apparatus of claim 1, comprising the test structure on which the etching process and/or the deposition process has been implemented.

6. The apparatus of claim 1, further comprising a process gas providing unit for providing a process gas to the test structure to implement the etching process and/or the deposition process thereon using the particle beam.

7. The apparatus of claim 1, further comprising a shielding element for electrical and/or magnetic shielding, wherein the shielding element has a through opening for the particle beam to pass through to the sample, wherein the shielding element and/or a holding element for holding the shielding element comprises the test structure.

8. The apparatus of claim 1, further comprising an aligning unit for aligning the particle beam and the test structure relative to each other such that the particle beam is incident on the test structure.

9. The apparatus of claim 1, wherein the at least one determined operating parameter comprises a telecentricity of the providing unit.

10. The apparatus of claim 1, comprising:
an exciter unit for inducing the test structure to mechanically vibrate,
a detecting unit for detecting a vibration property of at least the test structure, and
a determining unit for determining at least one current operating parameter and/or process parameter of the apparatus depending on the vibration property detected.

11. The apparatus of claim 10, wherein the test structure is formed on a cantilever.

12. The apparatus of claim 10, wherein the detecting unit is set up to detect the vibration property by use of a laser.

13. The apparatus of claim 10, further comprising a process gas provision unit for providing a process gas to the sample, wherein the determining unit is set up to determine at least one partial pressure and/or at least one gas concentration of a species present in the process gas depending on the vibration property detected.

14. A system comprising the apparatus of claim 1 and a sample.

15. The system of claim 14, wherein the apparatus is configured for implementing an etching process and/or a deposition process on the sample using the particle beam.

16. The system of claim 14, wherein at least a portion of the test structure and at least a portion of the sample have an identical material composition.

17. A method for providing a test structure in an apparatus for analysing and/or processing a sample with a particle beam, wherein the apparatus comprises:
a providing unit being configured for providing the particle beam, the providing unit having an opening for the particle beam to pass through to the sample; and
the test structure attached to the providing unit, the test structure being arranged inside or adjacent to the opening of the providing unit;
wherein the method comprises:
implementing an etching process and/or a deposition process on the test structure using the particle beam.

18. A method for analysing and/or processing a sample with a particle beam using an apparatus, comprising:
performing the method of claim 17;
detecting an interaction of the particle beam with the test structure; and
determining at least one current operating parameter and/or process parameter of the apparatus depending on the interaction detected.

19. The system of claim 14, wherein the test structure is arranged inside an inner volume defined by the providing unit.

20. The system of claim 14, further comprising an electron microscope, wherein the test structure is arranged within a depth of field of the electron microscope.
